(19) United States
(12) Patent Application Publication
(10) Pub. No.: US 2024/0052493 A1
(43) Pub. Date: Feb. 15, 2024

(54) METHODS OF DEPOSITING ALUMINUM NITRIDE TEMPLATING LAYERS USING THERMAL PULSED CHEMICAL VAPOR DEPOSITION FOR THE ENHANCEMENT OF ALUMINUM NITRIDE THICK FILMS AND RELATED FILMS

(71) Applicant: The Regents of the University of California, Oakland, CA (US)

(72) Inventors: Aaron McLeod, La Jolla, CA (US); Scott Ueda, Whittier, CA (US); Andrew Kummel, San Diego, CA (US)

(21) Appl. No.: 18/311,011

(22) Filed: May 2, 2023

Related U.S. Application Data
(60) Provisional application No. 63/364,005, filed on May 2, 2022.

(51) Int. Cl. C23C 28/04

(52) U.S. Cl. CPC C23C 28/04

(57) ABSTRACT

This invention allows for the deposition of aluminum nitride buffer layers and templating films that greatly enhance the quality of additional aluminum nitride deposited by alternate deposit ion techniques and reduce the overall thickness of needed buffer layers. Furthermore, these films can be deposited at substrate temperatures of 400° C. and 580° C. which is considerably lower than other techniques, such as molecular beam epitaxy (MBE) and metal organic chemical vapor deposition (MOCVD).

### CLAIM FOR PRIORITY

The present application claims the benefit of U.S. Provisional Application Ser. No. 63/364,005, filed May 2, 2022, the entirety of which is incorporated herein by reference.

### STATEMENT OF GOVERNMENT SUPPORT

This invention was made with government support under Grant No. HR0011-18-3-0004 awarded by the Department of Defense Advanced Research Projects Agency (DARPA). The government has certain rights in the invention.

### FIELD

The present inventive concept relates to methods of depositing layers and enhancement of methods of preparing thick films, such as metal nitride films.

### BACKGROUND

Aluminum nitride (AlN) is a promising material due to its high thermal conductivity and close lattice match to gallium nitride (GaN) and indium gallium nitride (InGaN). Accordingly, AlN can have application as a heat spreading material, as a buffer layer material, and/or as a template layer material. Deposition methods that provide crystalline aluminum nitride typically require temperatures exceeding 800° C., such as metal organic chemical vapor deposition (MOCVD) and molecular beam epitaxy (MBE); this presents barriers to integration in back-end-of-line (BEOL) processing. For application of AlN as a buffer layer for the growth of GaN and InGaN on silicon (Si) and silicon carbide (SiC), high-quality crystalline AlN films with c-axis orientation are necessary. Deposition methods at comparatively lower temperatures (˜350° C.), such as plasma-enhanced ALD (PE-ALD) and atomic layer annealing (ALA), can be used to deposit crystalline or polycrystalline AlN with less strain than films deposited at higher temperatures; however, PE-ALD produces non-stoichiometric AlN films that are often nano-crystalline. Atomic layer annealing has recently drawn attention for low temperature deposition of crystalline or polycrystalline AlN, however its practical utility is limited by low deposition rates due to lengthy ion bombardment treatments and the relative complexity of required deposition tools.

Accordingly, improved methods for preparing thin films, such as for use as a heat spreading material, a templating layer, and/or a buffering layer, as well as for use in preparing III-IV semiconductors on, for example, silicon or silicon carbide (SiC), for use in electronic devices, such as radio frequency, power, and/or microLED devices, are needed.

### SUMMARY

This present inventive concept is related to a method for formation of high-quality, metal nitride films for applications as a buffer layer and/or template layer. AlN has the advantage of being both a good conductor of heat as well as an electrical insulator and as such it is of great interest for use as a heat spreading material in RF circuits as well in 3D heterogeneous integration (packaging) of logic and/or memory devices. Using either trimethyl aluminum (TMA) and hydrazine (N₂H₄) or tris(dimethylamido) aluminum (TDMAA) (or related compounds such as tris(diethylamido) aluminum) and N₂H₄, high-quality AlN films are deposited with large grain size and low oxygen/carbon contamination can be used as a templating layer for further film growth. As heat spreading layers often need to be in excess of 1 μm thick, film growth of a template layer through pulsed chemical vapor deposition (CVD) of TDMAA and N₂H₄ at <580° C., followed by further film growth through sputter deposition, to yield high quality metal nitride polycrystalline films, such as AlN, GaN, or InGaN sputtered on an AlN template layer, are encompassed by aspects of the present inventive concept.

Accordingly, in an aspect of the present inventive concept, provided is a method of preparing a thin film layer comprising at least one cycle of: exposing a surface of a substrate to an organometallic chemical precursor; and exposing the organometallic chemical precursor to a nitrogen-containing co-reactant to provide a metal nitride layer on the substrate, wherein the at least one cycle is performed at a temperature at or less than about 580° C., or less than about 400° C.

In another aspect of the present inventive concept, provided is a method of preparing a crystalline metal nitride layer comprising at least one cycle of: exposing a surface of a substrate to an organometallic chemical precursor; and exposing the organometallic chemical precursor to a nitrogen-containing co-reactant to provide a metal nitride template layer on the substrate, followed by: depositing a second metal nitride layer on the template layer to provide the crystalline metal nitride layer, wherein the at least one cycle is performed at a temperature at or less than about 580° C., or less than about 400° C.

In another aspect of the inventive concept, provided is a method of preparing a crystalline metal nitride layer comprising at least one cycle of: exposing a surface of a Si or SiC substrate to an TDMAA or TDEAA chemical precursor; and exposing the organometallic chemical precursor to a N₂H₄ co-reactant to provide an AlN template layer on the substrate, followed by, depositing a an AlN, GaN, or InGaN layer on the template layer to provide the crystalline metal nitride layer, wherein the at least one cycle comprises pulsed CVD, wherein the at least one cycle is performed at a temperature at or less than about 580° C., and wherein deposition of the AlN, GaN, or InGaN layer comprises sputtering.

### BRIEF DESCRIPTION OF THE DRAWINGS

Throughout the drawings, reference numbers can be re-used to indicate correspondence between referenced elements. The drawings are provided to illustrate embodiments of the present disclosure and do not to limit the scope thereof.

FIG. 1 depicts a chamber schematic diagram showing separate pulsed CVD and ALA chamber (bottom right), sputtering chamber (bottom left), and analytical chamber (top) linked through an in-vacuum transfer system.

FIG. 2 depicts film composition data for pulsed CVD AlN vs. temperature at substrate temperatures of 400° C. (44.9 nm thick) and 580° C. (43.8 nm thick) on Si(111) as determined by XPS. Note, these are surface compositions, and bulk contaminants may be lower.

FIGS. 3A-3H depict high resolution X-Ray photoelectron spectra of the Al2p, N1s, O1s, and C1s regions for films deposited by (FIGS. 3A-3D) the 400° C. and (FIGS. 3E-3H) 580° C. pulsed CVD AlN processes on Si(111).

FIG. 4 depicts a GI-XRD comparison of deposition performed at 400° C. and 580° C. on Si(111), left, and Si(100), right. Polycrystallinity with preferential c-axis orientation is observed on both substrates at 580° C., whereas deposition at 400° C. is nanocrystalline on Si(111) and amorphous on Si(100).

FIG. 5 depicts X-Ray reflectivity profiles for the films deposited at 400° C. on Si(111) and Si(100), and at 580° C. on Si(111) and Si(100), panels a, b, c, and d, respectively.

FIG. 6 depicts BF-TEM (Panels a and b) and DF-TEM (Panels c and d) of films deposited by pulsed CVD on Si(111) substrates at 400° C. and 580° C. Panel a): The film deposited at 400° C. shows nanocrystalline regions that are likely connected by amorphous AlN. Panel b): At 580° C. substrate temperature, the crystallites take on a columnar structure with visible grain boundaries and increasing diameter with film thickness. Panel c): The presence of disconnected and weakly diffracting crystallites by DF-TEM indicates that a nanocrystalline film was deposited at 400° C. Panel d): Deposition at 580° C. shows several strongly diffracting grains with cohesive structure and columnar shape.

FIG. 7 depicts a STEM Comparison of 580° C. CVD and 400° C. ALA Templated Films and GI-XRD Comparisons STEM Comparison of grain structure by STEM in 580° C. pulsed CVD-templated sputtered AlN (left) and 400° C. ALA-templated sputtered AlN (right) on Si(111). Grain boundaries are manually traced in the top sputtered layer to visually aid in comparison. The ALA template layer is 21 nm thick while the pulsed CVD template later is 31 nm thick, yet both templated films show columnar grains with comparable crystallite widths. The center inset shows a GI-XRD comparison of the 580° C. pulsed CYD templated stack, the ALA templated stack, and a 190 nm thick reference sample sputtered directly onto Si(111). Note that both ALA and pulsed CVD template layers promote a preferential AlN(002) orientation, whereas orientation is randomized in the sputtering reference sample. The AlN(002) peak FWHM for the ALA templated film, the pulsed CVD templated film, and the sputtered film are 0.64°, 0.64°, and 0.79° respectively. This corresponds to average crystallite sizes of 13.7 nm for both the ALA templated and CVD templated films, and 11.1 nm for the sputtered film.

FIG. 8 depicts a Bragg-Brentano XRD comparison of the AlN(002) diffraction peaks of three films on 4H—SiC with 190 nm total thickness. The first film is an entirely sputtered film with a 0.38° FWHM and a 22.9 nm average crystallite size as determined by the Scherrer Equation. The second film consists of a 20 nm pulsed 580° C. CVD template layer followed by 170 nm of sputtered material with a 0.17° FWHM. The third film is composed of a 40 nm 580° C. pulsed CVD templating layer followed by 150 nm of sputtered AlN; the FWHM of this peak is 0.18°.

FIG. 9 depicts electron microscopy comparisons of a 580° C. pulsed CVD templated film and a directly sputtered film on SiC substrates. TEM (Panels a and d), selected area electron diffraction (Panels b and e), and HR-TEM (Panels c and f) of the 20 nm 580° C. CVD templated film (top row) and the directly sputtered film (bottom row) on 4H-SiC substrates. The 580° C. CVD layer demonstrates a long-range epitaxial relationship with the SiC whereas the directly sputtered film results in an initial amorphous layer that negates the possible benefits of the will-matched SiC—AlN lattice structures.

FIG. 10 depicts a fast Fourier transform analysis of a CVD-templated film on SiC. TEM image of the 20 nm 580° C. CVD templated-170 nm sputtered AlN film on SiC with matching FFT patterns for the substrate (I-V), 580° C. CVD AlN layer (VI-X), and the sputtered AlN layer (XI-XV) at the bottom.

### DETAILED DESCRIPTION

The foregoing and other aspects of the present invention will now be described in more detail with respect to other embodiments described herein. It should be appreciated that the invention can be embodied in different forms and should not be construed as limited to the embodiments set forth herein. Rather, these embodiments are provided so that this disclosure will be thorough and complete, and will fully convey the scope of the invention to those skilled in the art.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

The term “comprise,” as used herein, in addition to its regular meaning, may also include, and, in some embodiments, may specifically refer to the expressions “consist essentially of” and/or “consist of” Thus, the expression “comprise” can also refer to, in some embodiments, the specifically listed elements of that which is claimed and does not include further elements, as well as embodiments in which the specifically listed elements of that which is claimed may and/or does encompass further elements, or embodiments in which the specifically listed elements of that which is claimed may encompass further elements that do not materially affect the basic and novel characteristic(s) of that which is claimed. For example, that which is claimed, such as a composition, formulation, method, system, etc. “comprising” listed elements also encompasses, for example, a composition, formulation, method, kit, etc. “consisting of,” i.e., wherein that which is claimed does not include further elements, and a composition, formulation, method, kit, etc. “consisting essentially of,” i.e., wherein that which is claimed may include further elements that do not materially affect the basic and novel characteristic(s) of that which is claimed.

The term “about” generally refers to a range of numeric values that one of skill in the art would consider equivalent to the recited numeric value or having the same function or result. For example, “about” may refer to a range that is within ±1%, ±2%, ±5%, ±10%, ±15%, or even ±20% of the indicated value, depending upon the numeric values that one of skill in the art would consider equivalent to the recited numeric value or having the same function or result. Furthermore, in some embodiments, a numeric value modified by the term “about” may also include a numeric value that is “exactly” the recited numeric value. In addition, any numeric value presented without modification will be appreciated to include numeric values “about” the recited numeric value, as well as include “exactly” the recited numeric value. Similarly, the term “substantially” means largely, but not wholly, the same form, manner or degree and the particular element will have a range of configurations as a person of ordinary skill in the art would consider as having the same function or result. When a particular element is expressed as an approximation by use of the term “substantially,” it will be understood that the particular element forms another embodiment.

Unless otherwise defined, all technical and scientific terms used herein have the same meaning as commonly understood by one of ordinary skill in the art to which this invention belongs.

This inventive concept allows for the deposition of aluminum nitride thin films for applications as heat spreader films, buffer layers, and/or templating films, that, in some embodiments, greatly enhance the quality of additional metal nitride, such as aluminum nitride, deposited by alternate deposition techniques and can reduce the overall thickness of needed buffer layers. Furthermore, these buffer and/or templating films/layers can be deposited at substrate temperatures of, for example, about 350° C., 400° C., about 450° C., about 500° C., about 550° C., and/or 580° C., which is considerably lower than other techniques, such as molecular beam epitaxy (MBE) and metal organic chemical vapor deposition (MOCVD), and include use of, for example, an AlN film, or in the alternative, a GaN, film and/or an InN film deposited on a substrate by, for example, chemical vapor deposition (CVD), such as pulsed CVD, or atomic layer annealing (ALA) as a buffer/template layer for further crystalline film growth thereon by, for example, sputtering, in the fabrication of films/layers.

The term “substrate,” as used herein, can broadly refer to any layer and/or surface upon which processing is desired. Thus, for example, a native oxide film on the surface of a silicon substrate may itself be considered a substrate for the purposes of this discussion. Likewise, layers deposited on silicon or on other base substrates may likewise be considered substrates in some embodiments. For example, in some embodiments, a multi-layer stack may be formed, and then atomic layer deposition and/or atomic layer annealing may be performed on the top layer, or a surface of the top layer, of the stack. In such a case, the top layer may be considered the substrate. In general, the layer or layers upon which the chemical precursor is deposited and/or which reacts with the chemical precursor can be considered the substrate layer(s). The material for the substrate may be any that may be appreciated by one of skill in the art in the field of electronics and/or semiconductors. In some embodiments, materials for the substrate include, for example, Si, and/or SiC. In some embodiments, the SiC may be 4H—SiC. In some embodiments, the SiC may be 6H—SiC.

The substrate, according to some embodiments, may include, but is not limited to, wafers. The wafers may be of various suitable processing sizes. For example, substrate samples may be on the order of 1 inch or smaller, if desired. Additionally, full wafers of about 200 mm or about 300 mm in diameter, or even larger substrates may be incorporated.

The term “chemical vapor deposition (CVD),” “atomic layer annealing” (ALA), and “atomic layer deposition” (ALD), as used herein, can broadly refer to the level of layer dimensional control that can be achieved at the angstrom (A) level. Thus, atomic layer deposition may generally correspond to the size of atoms and/or molecules. The average added layer thickness per cycle of CVD/ALA/ALD can be less than 1 Å (0.1 nm) per deposition cycle, for example, about 0.5 Å, about 0.6 Å, about 0.7 Å, about 0.8 Å, about 0.9 Å, about 1 Å, or more than 1 Å, for example, about 1.1 Å, about 1.2 Å, about 1.3 Å, about 1.4 Å, about 1.5 Å, about 2 Å, about 2.5 Å, about 3 Å, about 4 Å, about 5 Å, about 6 Å, about 7 Å, about 8 Å, about 9 Å, about 10 Å (1 nm), or any number between about 0.1-30 Å per deposition cycle. In some embodiments, the average added layer thickness per cycle is between about 0.1-4 Å, about 0.5-4 Å per deposition cycle, about 0.6-4 Å, about 0.7-4 Å per deposition cycle, about 0.8-4 Å per deposition cycle, about 0.9-4 Å per deposition cycle, about 1-4 Å per deposition cycle, about 1-2 Å per deposition cycle, about 1-1.5 Å per deposition cycle, or about 1.2-1.5 Å per deposition cycle. Similarly, the number of deposition cycles in the pulsed CVD/ALA/ALD process is not particularly limited, and may be any number of cycles that would be appreciated by one of skill in the art. For example, the number of deposition cycles in the process may be between 1 and about 1,000 cycles. In some embodiments, the number of deposition cycles may be between about 1-600 cycles, for example, 1 cycle, about 5 cycles, about 10 cycles, about 20 cycles, about 30 cycles, about 40 cycles, about 50 cycles, about 75 cycles, about 100 cycles, about 150 cycles, about 200 cycles, about 250 cycles, about 300 cycles, about 350 cycles, about 400 cycles, about 450 cycles, about 500 cycles, about 550 cycles, or about 600 cycles, or any number of deposition cycles between and including 1 deposition cycle and about 1,000 deposition cycles. The term “pulsed CVD,” as used herein, may denote a CVD process, that through short exposure/pulse times to the precursors, does not display self-limiting growth, as may be characteristic of ALD processes. Exposure/pulse times for a pulsed CVD may be, for example, about 70-170 ms for an organometallic precursor, such as a metal nitride precursor, and about 60-120 ms for a co-reactant, such as a nitrogen-containing co-reactant. In some embodiments, the metal nitride films/layers provided by methods of the inventive concept may be aluminum nitride (AlN) films/layers. In some embodiments, the metal nitride films/layers may be gallium nitride (GaN) films/layers. In some embodiments, the metal nitride films/layers may be indium gallium nitride (InGaN) films/layers. In some embodiments, the metal nitride precursors for preparing AlN films/layers include, e.g., trimethyl aluminum (TMA), tris(dimethylamido) aluminum (TDMAA), and/or tris(diethylamido) aluminum. In some embodiments, the metal nitride precursors for preparing GaN films/layers include, e.g., trimethyl gallium (TMG), tris(dimethylamido) gallium (TDMAG), and/or tris(diethylamido) gallium (TDEAG). In some embodiments, the metal nitride precursors for preparing InGaN films/layers may include trimethyl indium (TMI). In some embodiments, the nitrogen-containing co-reactant for preparing metal nitride films/layers may include hydrazine (N₂H₄). In some embodiments, the nitrogen-containing co-reactant for preparing metal nitride films/layers may include ammonia (NH₃)

In addition to, for example, exposing a substrate to at least one cycle of a pulse of an organometallic chemical precursor and a pulse of a co-reactant of an ALD process, optionally including a purge between the pulse, or pulses, of precursor and co-reactant, methods of the inventive concept may include a plasma treatment, such as an inert/noble gas plasma treatment with, for example, argon (Ar), neon (Ne), krypton (Kr), or helium (He) plasma, under a bias voltage, for example, about −5 V, −10 V, about −15 V, about −20 V, about −25 V, about −30 V, about −40 V, about −50 V, or about −75 V bias voltage. In some embodiments, the bias voltage in the plasma treatment is between about −5 V and about −75 V. In some embodiments the bias voltage in the plasma treatment is between about −25 V to about −40 V. The plasma treatment may occur after each ALD cycle, after every other ALD cycle, or regularly after any number of ALD cycles. In some embodiments, the plasma treatment is provided after each ALD cycle of an organometallic chemical precursor pulse and a nitrogen-containing co-reactant pulse. In some embodiments, the plasma treatment is provided after every other ALD cycle of an organometallic chemical precursor pulse and a nitrogen-containing co-reactant pulse. In some embodiments, the plasma treatment is provided after every third ALD cycle of an organometallic chemical precursor pulse and a nitrogen-containing co-reactant pulse.

It will be appreciated that temperatures at which methods of deposition of films/layers, such as deposition of templating films/layers and/or buffer films/layers and the like, of the inventive concept should be such that the methods of deposition may be compatible with back end of line (BEOL) processing and integration. In some embodiments, the temperature at which methods of the present inventive concept take place is less than or equal to about 400° C. In some embodiments, the temperature at which methods of the present inventive concept take place is less than or equal to about 450° C., less than or equal to about 500° C., less than or equal to about 550° C., less than or equal to about 580° C., or less than or equal to about 600° C. In some embodiments, the temperature at which methods of the present inventive concept take place is between about and including 350° C. and about and including 400° C. In some embodiments, the temperature at which methods of the present inventive concept take place is between about and including 350° C. and about and including 580° C., between about and including 400° C. and about and including 580° C., between about and including 450° C. and about and including 580° C., between about and including 500° C. and about and including 580° C., between or about and including 550° C. and about and including 580° C.

The pressures at which methods and steps in the methods of the present inventive concept are not particularly limited, and may be any pressure may be used that would be envisioned by one of skill in the art to perform the methods and steps in the methods as described herein. For example, the organometallic chemical precursor pulse(s) and the nitrogen-containing co-reactant pulse(s) may be performed at pressures between about 10⁻⁸ Torr to about 10⁻² Torr. In some embodiments, the deposition/pulses may be performed at a base pressure at or less than about 1×10⁻⁴ Pa (about 7.5×10⁻⁷ torr) The pressures at which the plasma treatment takes place may be between about 10⁻⁴ Torr to about 10⁻² Torr, for example, but not limited to, about 4×10⁻³ Torr or about 5×10⁻³ Torr.

Methods of the inventive concept include preparing and depositing thin films/layers, such as a first, template/buffer layer, upon which a second, further layer/film, such as a thick or thicker layer/film (e.g., thicker than about 70 nm), may be grown/deposited. In some embodiments, the first, template/buffer layer may have a thickness of about 20-50 nm, about 20-40 nm, or about 20-30 nm, and may be prepared, for example, by pulsed CVD at a temperature of about 580° C., or by ALA at a temperature of about 400° C. The second, further layer/film may have a thickness of about 100-500 nm, about 100-400 nm, about 100-300 nm, about 100-200 nm, about 100-190 nm, about 150-190 nm, or about 150-170 nm, and may be deposited by, for example, sputtering, in a process that, in some embodiments, is performed without active substrate heating, i.e., heat is not intentionally or purposefully applied to the substrate. In some embodiments, the process takes place at a temperature of less than, e.g., about 100° C., such as between about 20-80° C. during and following deposition of the second, further layer/film. In some embodiments, the average crystallite grain size of AlN in the thin film/layer may be about 6-25 nm, for example, about 6-8 nm, about 10-15 nm, about 10-25 nm, or about 20-25 nm. In some embodiments, the average crystallite grain size of AlN in the thin film/layer and/or the second, further layer/film may be about 10 nm or greater. In some embodiments, the average crystallite grain of the second, further film/layer may be about 20 nm or greater, about 30 nm or greater, about 40 nm or greater, about 50 nm or greater, about 60 nm or greater, about 70 nm or greater, about 80 nm or greater, about 90 nm or greater, up to about 100 nm in size.

Having described various aspects of the present invention, the same will be explained in further detail in the following examples, which are included herein for illustration purposes only, and which are not intended to be limiting to the invention.

### EXAMPLES

The examples that follow show the use of tris(dimethylamido) aluminum (TDMAA) at 400° C. and 580° C. to deposit AlN by a pulsed chemical vapor deposition (CVD) method on non-lattice matched (Si) substrates and lattice-matched (SiC) substrates with growth rates up to ˜45 nm/h. At 580° C. the films show growth of columnar grains. Films produced by the pulsed CVD method at 580° C. template preferentially in the c-axis orientation in additional AlN deposited by reactive sputtering. Films prepared at 400° C. and 580° C. show a similar result in enhancing AlN(002) orientation. On 4H—SiC, epitaxy is observed in the 580° C. pulsed CVD method, which greatly enhances the crystallinity of low temperature (<100° C.) sputtered material when used as a templating layer.

### Materials and Methods

### Substrates and Preparations

Silicon wafers with (100) and (111) orientations were obtained from WaferWorld. Silicon carbide wafers of 4H polymorph with a 4° off-c-axis cut were obtained from El Cat, Inc. Substrate coupons were degreased using acetone, methanol, and water (Fisher Scientific) and stripped of native oxide by a three-step cyclic etch in 2% HF in deionized water (VWR). Tris(dimethylamido) aluminum (III) was supplied by EMD Performance Materials; anhydrous hydrazine was supplied by RASIRC.

### Chemical Vapor Deposition System

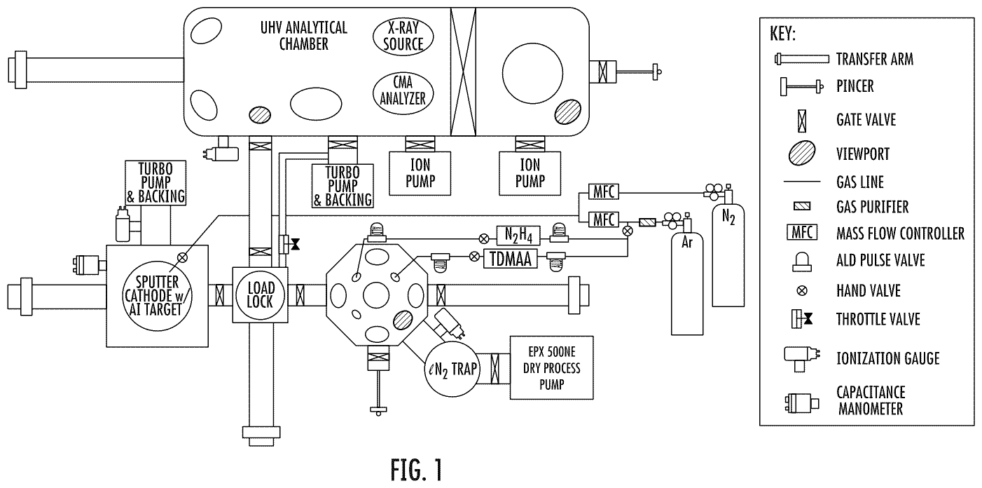

The pulsed CVD was performed in a homebuilt vacuum chamber (walls heated to 90° C., base pressure <1×10⁻⁴ Pa) pumped by an Edwards EPX 500 NE high vacuum pump with an in-line liquid nitrogen trap. A tool schematic is shown in FIG. 1. The deposition chamber is attached to two additional vacuum chambers through an in-vacuum transfer system: the first containing a sputtering system and the second containing an x-ray photoelectron spectroscopy system.

The pulsed CVD process was performed at substrate temperatures of 400° C. and 580° C. The TDMAA precursor container was heated to 105° C. for deposition and held at 85° C. for storage. All precursor dosing was controlled by a LabView system and was performed in a manner consistent with ALD: the precursors were pulsed in an alternating fashion separated by brief periods of pumping. The process is denoted as pulsed CVD because the TDMAA precursor did not display self-limiting growth, as is characteristic of ALD processes, for the short pulse times utilized in this study. Similar behavior has been observed for the deposition of AlN using TDMAA and NH₃. Both precursor containers were pressurized with Ar prior to dosing; trace water and oxygen were removed from the Ar push gas using an Entegris GateKeeper purifier. The pulse times used for 400° C. and 580° C. deposition are shown in Table 1 and were optimized to achieve 1.2-1.5 Å/cycle growth rates.

### Deposited Thin Films and CVD-Templated Sputtered Films

Table 2 describes the samples deposited for the three studies performed. An initial set of thin films with 40 nm target thickness were deposited by pulsed CVD on Si(111) and Si(100) at 400° C. and 580° C. to evaluate the effects of lattice mismatch and substrate temperature. A second set of depositions was performed on Si(111) to analyze the templating ability of the 580° C. pulsed CVD relative to a previously reported ALA technique using Ar ions bombardment at −25 V DC substrate bias: a 20-30 nm template layer by either method was first deposited followed by 150-170 nm of sputtered AlN. These two templated films are compared to a reference 190 nm AlN sputtered film deposited directly onto Si(111). A third set of depositions compares the effectiveness the 580C pulsed CVD template layers on 4H—SiC to a reference sputtered film; 20 nm and 40 nm template layers were deposited and all samples were brought to a total thickness of 190 nm by reactive sputtering. For all templated samples layer thicknesses are approximate and were based on observed growth rates. Reactive sputtering was performed using a 69% N2/31% Ar gas mixture (Praxair and AirGas, >99.999%) in a balanced magnetron configuration (Kurt J. Lesker Torus MagKeeper, >99.99% purity Al target) with 100 W DC power operating at 0.43 Pa as measured by a capacitance manometer (Kurt J. Lesker Co.). Samples were not actively heated during sputter deposition, however a thermocouple mounted on the sputtering stage showed increases from 20° C. to 70-80° C. following deposition.

The surface composition of the films was determined by x-ray photoelectron spectroscopy (STAIR Instruments DESA 150 CMA, Mg Kα source) of the Al2p, N1s, C1s, O1s and Si2p regions. Peak fitting (CASA XPS) was performed using a Shirley background profile and elemental composition was corrected using Scofield relative sensitivity factors. All photoelectron spectra were referenced to adventitious carbon at 284.8 eV.

### Characterization

For all film depositions on Si(111) and Si(100), grazing incidence x-ray diffraction (GI-XRD) was performed to analyze film crystallinity and preferred orientation (Rigaku SmartLab, Cu anode operating at 2 kW, parallel beam configuration, fixed 1.005° incidence angle). X-ray reflectivity measurements of the thin film samples from 0 to 3° 2θ were performed on the same instrument and were modeled using Rigaku GlobalFit software to determine film thickness and density. Bragg-Brentano x-ray diffraction was used for films deposited on SiC due to its comparatively lower instrumental broadening; this allowed for resolution of AlN and SiC diffraction peaks that are not easily resolved in GI-XRD.

Four types of transmission electron microscopy (TEM) were performed: bright filed (BF-TEM), dark field (DF-TEM), scanning (STEM), and high-resolution (HR-TEM). Selected area electron diffraction (SAED) was also performed for films on SiC. All lamellae were prepared using a focused ion beam (FIB) milling system with thinning to approximately 40 nm by Covalent Metrology (Sunnyvale, CA). All TEM, STEM, and SAED was performed using a ThermoFisher Talos F200X G2 transmission electron microscope.

### Results and Discussion

### Thin Films

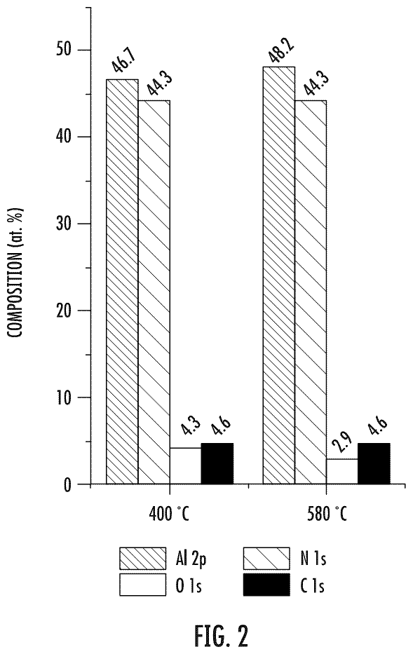

Representative composition data as determined by XPS is shown in FIG. 2 for pulsed CVD thin film depositions at 400 and 580° C. on Si(111). At both substrate deposition temperatures, nearly 1:1 stoichiometric Al:N is observed with minimal oxygen and carbon content. The composition information reflects the composition of the top 3-5 nm of the AlN films. In-vacuum transfer of the substrates through the load lock after deposition may result in slight oxidation of the AlN surface, meaning bulk oxygen content is likely lower than is the surface composition determined by XPS and shown in FIG. 2.

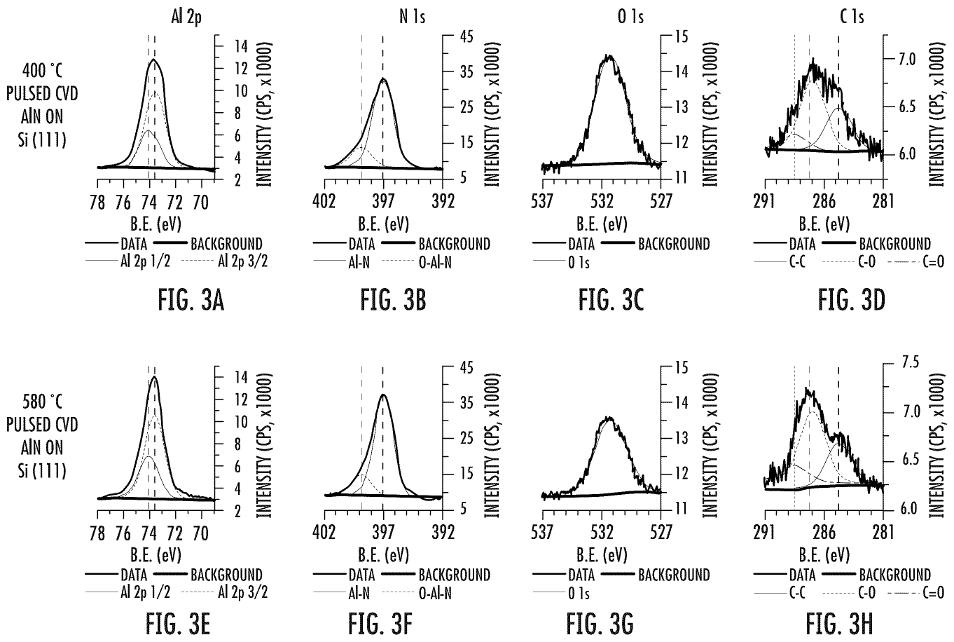

Photoelectron spectra and corresponding peak fits used for the determination of film composition of these samples are shown in FIGS. 3A-3H. The Al2p regions in FIGS. 3A and 3E are fitted with a spin orbit split binding energy difference of 0.4 eV. The C1s x-ray photoelectron spectra in FIGS. 3D and 3H indicate adventitious hydrocarbon contamination of the film surfaces due to the presence of peaks at 284.8 eV, 287.3 eV, and 288.5 eV, corresponding to C—C, C—O, and C═O bonds. At both deposition temperatures, no low binding energy peak is observed in the C1s region indicating the absence of Al—C bonds. These observations indicate that the carbon content in the bulk of these films is likely lower than is observed on the film surface. This low carbon contamination is consistent with previous reports of TDMAA used for deposition of AlN and AlOx and is attributed to the lack of Al—C bonds in the precursor structure.

Note the N1s spectra are fit using two peaks, as is customary in XPS characterization of aluminum nitride films; the main nitride peak is located at 397.0 eV and the higher binding energy peak at 398.8 eV corresponds to O—Al—N bonds likely present on the oxidized film surface. It is commonly reported that the charge-balanced sum of nitrogen and oxygen content should equal that of aluminum. While the stoichiometry of the bulk AlN was not measured (e.g., by depth profiling XPS), it is likely that the concentration of oxygen and nitrogen in the bulk of the films may equal that of aluminum and the films are, therefore, stoichiometric.

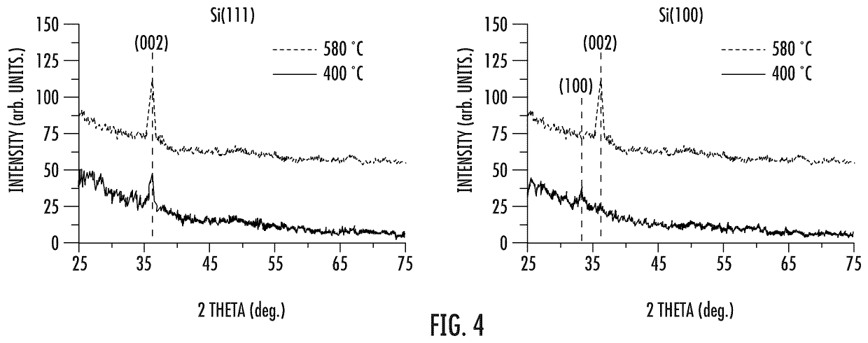

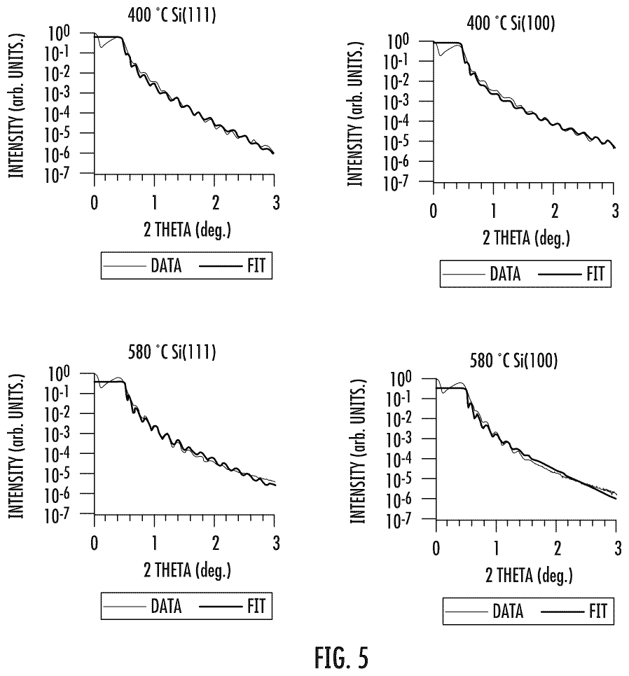

Results from the grazing-incidence x-ray diffraction study are shown in FIG. 4; Table 3 lists the corresponding film thickness and density values, as determined by XRR, and AlN (002) peak full-width at half maximum (FWHM) as determined by GI-XRD. Polycrystallinity with preferential c-axis orientation is observed on both substrates at 580° C. whereas deposition at 400° C. is nanocrystalline on Si(111) and amorphous on Si(100). On Si(111) (FIG. 4, panel a), crystallinity is observed at 580° C. with a preferred AlN(002) orientation, whereas at 400° C. minimal diffraction signal is observed at the AlN(100) peak position. The full-width at half maximum intensity (FWHM) of the AlN(002) peak on the 580° C. film is 0.73°, corresponding to an average crystallite size of 11.9 nm, at a position of 36.2° relative to a theoretical position of 36.1°. This may indicate that strain is present in the film, likely due to deposition on a non-lattice matched substrate. On Si(100) (FIG. 4, panel b), similar crystallinity is observed at 580° C. with an AlN(002) peak of 0.75° FWHM, corresponding to an average crystallite size of 11.6 nm, at a position of 36.1°. When depositing at 400° C. substrate temperature on Si(100), no crystallinity is detected. The XRR measurement and fit profiles for each film are shown in FIG. 5. The decrease in signal observed beyond 1.5° 2θ for the films deposited at 580° C. substrate temperature may be due to increased surface roughness, consistent with the growth of larger crystallites.

As listed in Table 3, the films deposited at 580° C. have greater density than their 400° C. counterparts, with increases of 8.4% and 17.6% observed for the films on Si(111) and Si (100), respectively. It is noted that the largest film density observed, 3.11 g/cm³ for the film deposited at 580° C. on Si(111), is still less than that of bulk AlN at 3.26 g/cm³. This is likely due to the presence of amorphous material at grain boundaries and at the Si—AlN interface.

The data in FIGS. 4, 5, and Table 3 demonstrate that moderate increases in substrate temperature during pulsed CVD, such as increasing from 400 to 580° C., can aid in developing crystalline structure on non-lattice matched substrates. The average crystallite size for any one condition is not limited by thickness as all films with observed crystallinity are of comparable thickness. The differences in crystallinity on Si(111) and Si(100) are consistent with the hexagonal wurtzite structure of aluminum nitride having a closer lattice match to the Si(111) face rather than the Si(100) face.

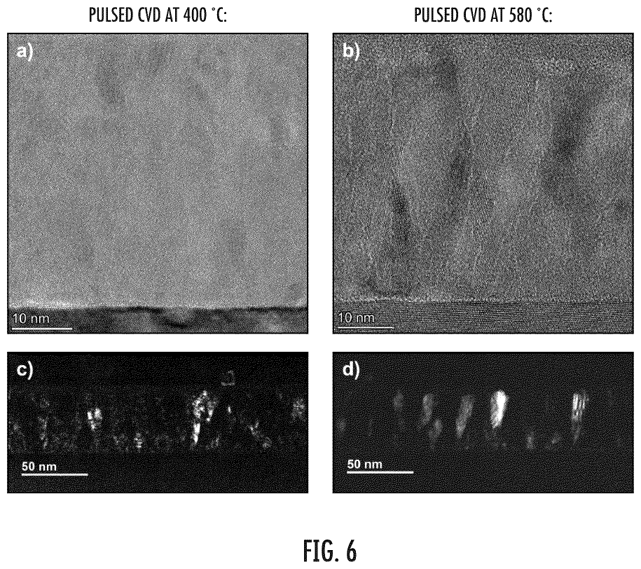

These GI-XRD results are complimented by the electron microscopy and diffraction studies of the thin films deposited at 400° C. and 580° C., shown in FIG. 6. Bright field TEM for these films is shown in panels a and b of FIG. 6, respectively. In the micrograph of the film deposited by pulsed CVD at 400° C., a nanocrystalline film with randomly oriented grains of −5 nm diameter is observed. In contrast, the film deposited at 580° C. shows crystallites coalescing and taking on a columnar structure in which the crystallite diameter increases as a function of film thickness. These observations are confirmed by aperture-based dark field TEM used to highlight separate crystallites, shown in FIG. 6, panels b and c. The 400° C. film appears nanocrystalline with rare instances of columnar grains. At 580° C., the columnar grain structure noted in bright field TEM is observed across the entire film as is evidenced by the diffraction of several columnar crystallites. When considering the GI-XRD, XRR, BF-TEM, and DF-TEM results altogether, it is evident that the 580° C. pulsed CVD process deposits films with superior crystallinity and more ordered grain structure than those deposited by the 400° C. process.

### Templated Sputtered Films on Si(111)

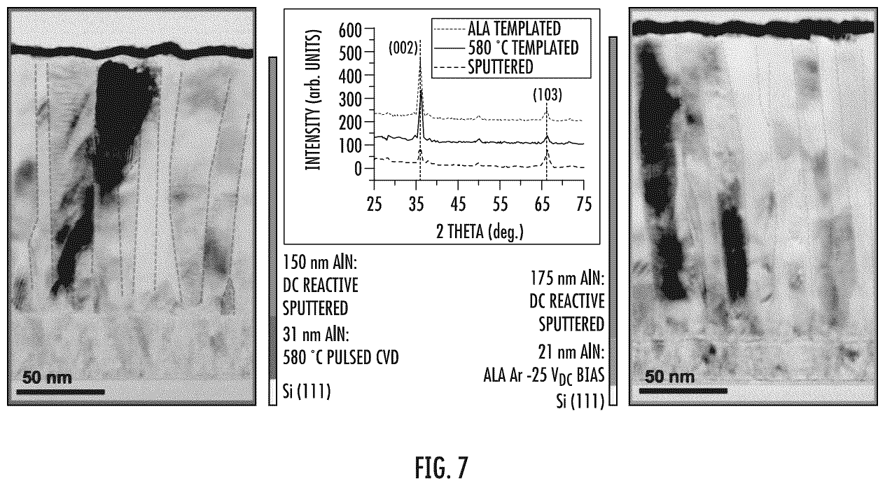

For AlN to be utilized as a buffer layer for the growth of GaN and InGaN on silicon and silicon carbide, goals of the RF and microLED industries, thicker layers with c-axis orientation are necessary. In FIG. 7, two samples of 181-196 nm total thickness are compared by STEM and GI-XRD: the first is a 31 nm layer of AlN deposited using the 580° C. pulsed CVD process to template 150 nm of sputtered AlN (red in GI-XRD); the second is a templated film comprised of an initial 21 nm layer of AlN deposited using ALA at 400° C. substrate temperature with 175 nm of sputtered AlN deposited on top (blue in GI-XRD); note the substrate temperature is below 100° C. during the sputtering process.

ALA was performed using a 20 s ion bombardment at the end of each precursor dosing cycle, with Ar ions generated by an inductively coupled plasma source. For this ion bombardment process, the substrate was biased to −25 V DC to accelerate the ions toward the growth surface to crystallize the material. Experimental details can be found previously. These two templated films are also compared to a reference film of 190 nm sputtered AlN on Si(111) by GI-XRD (black line in GI-XRD comparison). AlN deposited by this sputtering condition showed 49.4 at. % Al, 42.5 at. % N, 5.1 at. % O, and 3.1 at. % C composition by XPS.

The GI-XRD comparison inset (FIG. 7) shows that AlN(002) orientation is strongly preferred when the sputtering is performed on either the 580° C. pulsed-CVD or 400° C. ALA templating layer, both with AlN(002) FWHM of 0.64°. The sputtered reference film has an AlN (002) FWHM of 0.79° and shows mixed AlN(002) and AlN(103) orientation which is not desirable for the intended applications. The increase in preferential AlN(002) orientation is likely the result of local domain epitaxy across the template-sputtered interface, as both the 580° C. pulsed CVD process and 400° C. ALA process have been shown to deposit films with AlN (002) orientation. These results highlight that a templating layer deposited by pulsed CVD can be as effective as a templating layer deposited by the more complex ALA process in increasing the crystallinity of sputtered AlN.

### Templated Sputtered Films on SiC

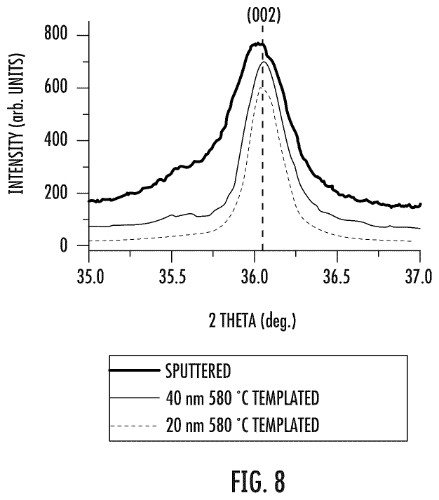

The crystallinity of sputtered material on 4H-SiC is also enhanced when grown on template layers deposited by the 580° C. pulsed CVD process. Shown in FIG. 8 is a Bragg-Brentano XRD comparison: the first film is comprised of 190 nm of AlN sputtered directly onto 4H—SiC, the second and third films are comprised of 20 and 40 nm of AlN deposited by the 580° C. pulsed CVD process which were brought to a total thickness of 190 nm with sputtered AlN. Relative to the reference sputtered film with 0.38° FWHM, the 20 and 40 nm templated films show drastically sharper peaks at 0.17° and 0.18° FWHM, respectively, indicating superior crystallinity of the templated films. This increase in crystallinity is particularly notable since the sample temperature during sputtering was below 100 C.

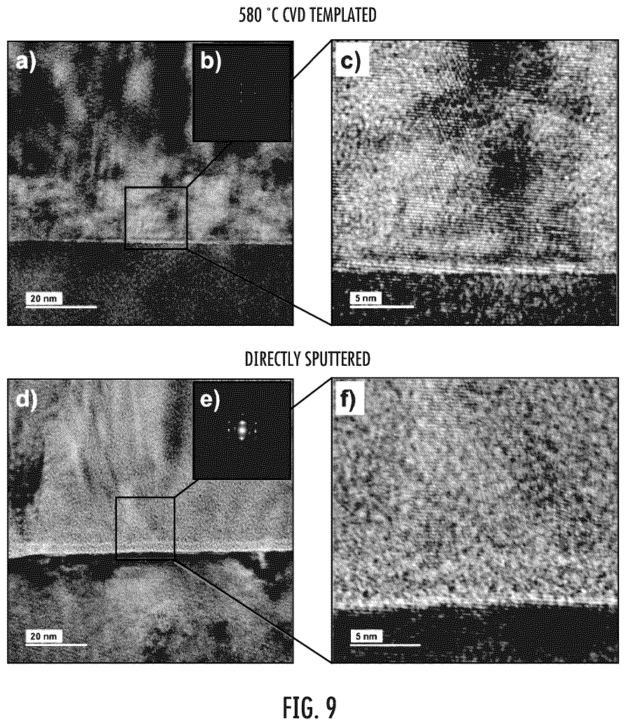

The efficacy of the pulsed CVD templating layers on SiC are made clear by the TEM, SAED, and HR-TEM shown in FIG. 9. The 20 nm template layer deposited by the 580° C. CVD process is shown in FIG. 9, panel a. This CVD layer is grown epitaxially, as is demonstrated by the SAED pattern in FIG. 9, panel b, which shows a single crystal-like pattern, and the HR-TEM shown in FIG. 9 panel c, where the lattice fringes of the SiC and AlN appear regularly spaced and uninterrupted. In comparison, TEM of the directly sputtered film in FIG. 9 panel d reveals an initial amorphous layer of −3-4 nm thickness. Additionally, the SAED pattern shown in FIG. 9, panel e reveals diffraction rings from a film of polycrystalline nature with grains at various tilt angles relative to the SiC diffraction pattern. The HR-TEM (FIG. 9, panel f) of this film more clearly shows this initial amorphous region, with crystallites developing quickly thereafter.

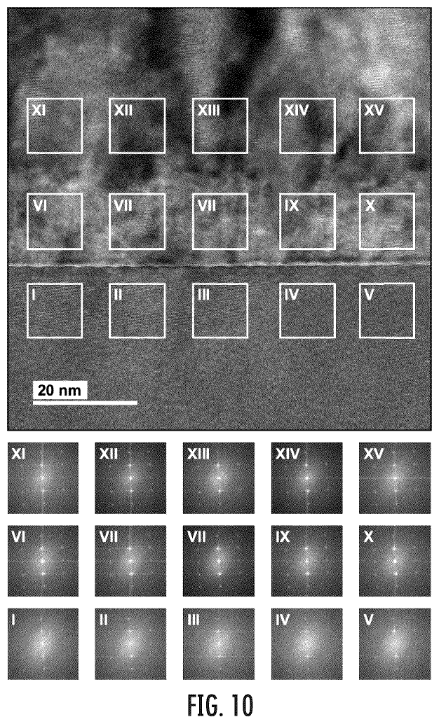

Further analysis of the epitaxial relationship of the CVD-templated sputtered film shown in FIG. 9, panel a is shown in FIG. 10. Fast Fourier transform (FFT) analysis was performed from the HR-TEM image for five ˜10×10 nm regions each of the substrate (I-V), the CVD layer (VI-X), and the sputtered layer (XI-XV). Each of the FFT regions shows the expected pattern for the 4H—SiC and AlN wurtzite structures, with matching orientation along the c-axis. This indicates that the epitaxial relationship observed between the SiC substrate and the CVD AlN layer creates long-range order and effectively templates the sputtered AlN layer.

The epitaxial growth of the 580° C. CVD template layer may be the result of comparatively greater adatom mobility on the growth surface due to the considerably higher substrate temperature and slower growth rate. In comparison, the initial amorphous region of the directly sputtered film may be the result of the combined higher deposition rate and a comparatively colder initial growth surface as the SiC substrate was not actively heated during sputtering. These effects likely resulted in constrained surface adatom mobility. For films deposited on SiC, these XRD, TEM, and SAED results demonstrate that the enhancement mechanism of the sputtered material is not a function of the CVD template layer thickness, but rather is the result of sputtering AlN onto a highly crystalline and lattice-matched CVD template layer.

### CONCLUSIONS

These results demonstrate that a 580° C. pulsed CVD process for aluminum nitride is a viable alternative to more complex techniques such as atomic layer annealing and techniques requiring substantially greater substrate temperatures, such as MBE and MOCVD. Using tris (dimethylamido) aluminum and anhydrous hydrazine, crystalline films with low oxygen and carbon content can be achieved at temperatures as low as 400° C., though substantial improvement in crystallinity and density is observed at 580° C. When performed on SiC substrates, the 580° C. process demonstrates an epitaxial relationship with the substrate and forms a single crystal; this greatly enhances the crystallinity of reactively sputtered AlN with no active substrate heating. This technique may be used for the growth of crystalline AlN buffer/templating layers for GaN and InGaN on silicon and silicon carbide, enabling a decrease in substrate costs for RF power electronics and for thermally conductive buffer layers for microLED devices.

TABLE 1
Pulsed CVD dosing conditions at 400° C. and 580° C.

| | |
|---|---|
| 400° C. | 580° C. |

| | | | | |
|---|---|---|---|---|
| TDMAA Dose | 150 | ms | 90 | ms |
| Post-TDMAA Pump | 4 | s | 4 | s |
| N₂H₄ Dose | 100 | ms | 80 | ms |
| Post- N₂H₄ Pump | 8 | s | 8 | s |

TABLE 2
List of sample depositions and deposition methods

| | | | Thin Film or | Sputtered | |
|---|---|---|---|---|---|
| Comparison | Sample | | Template Layer | Layer | Reference to |
| Set | Description | Substrate | Thickness (nm) | Thickness | Drawings |
| Thin Films | 400° C. Pulsed | Si(111) | 44.6 | N/A | FIGS. 2-6 |
| | CVD | Si(100) | 41.3 | | |
| | 580° C. Pulsed | Si(111) | 43.8 | | |
| | CVD | Si(100) | 44.6 | | |
| Templated | 580° C. Pulsed | Si(111) | 31 | ~150 | FIG. 7 |
| Films on | CVD | | | | |
| Si(111) | 400° C. ALA, | | 21 | ~175 | |
| | Ar −25 V DC | | | | |
| | Sputtered | | N/A | ~190 | |
| | Reference | | | | |
| Templated | 580° C. Pulsed | 4H-SiC | ~20 | ~170 | FIGS. 8 |
| Films on | CVD | | ~40 | ~150 | and 9 |
| 4H-SiC | Sputtered | | N/A | ~190 | |
| | Reference | | | | |

TABLE 3
Thin film properties as determined by
XRR and GI-XRD for pulsed CVD AlN

| | Deposition | Thick- | | AlN (002) | AlN (002) |
|---|---|---|---|---|---|
| | Temperature | ness | Density | FHWHM | Peak |
| Substrate | (° C.) | (nm) | (g/cm³) | (deg.) | Position (deg.) |
| Si (111) | 400 | 44.6 | 2.86 | N/A | N/A |
| | 580 | 43.8 | 3.11 | 0.73 | 36.2° |
| Si (100) | 400 | 41.3 | 2.59 | N/A | N/A |
| | 580 | 44.6 | 3.09 | 0.75 | 36.1° |

The foregoing is illustrative of the present invention and is not to be construed as limiting thereof. Further embodiments of the present inventive concept are exemplified in the following claims.

What is claimed is:

1. A method of preparing a thin film layer comprising at least one cycle of:
exposing a surface of a substrate to an organometallic chemical precursor; and
exposing the organometallic chemical precursor to a nitrogen-containing co-reactant to provide a metal nitride layer on the substrate,
wherein the at least one cycle is performed at a temperature at or less than about 580° C.

2. The method of claim 1, wherein the at least one cycle comprises chemical vapor deposition (CVD).

3. The method of claim 2, wherein the CVD comprises pulsed CVD.

4. The method of claim 1, wherein the thin film layer has a thickness of about 10-40 nm.

5. The method of claim 1, wherein the thin film layer comprises AlN.

6. The method of claim 1, wherein the organometallic precursor comprises trimethyl aluminum (TMA), tris(demethylamido) aluminum (TDMAA) or tris(diethylamido) aluminum (TDEAA).

7. The method of claim 1, wherein the nitrogen-containing co-reactant comprises hydrazine (N₂H₄) or ammonia (NH₃).

8. The method of claim 1, wherein the metal nitride layer has an average crystallite size of about 10 nm or greater.

9. A method of preparing a crystalline metal nitride layer comprising at least one cycle of:
exposing a surface of a substrate to an organometallic chemical precursor; and
exposing the organometallic chemical precursor to a nitrogen-containing co-reactant to provide a metal nitride template layer on the substrate, followed by:
depositing a second metal nitride layer on the template layer to provide the crystalline metal nitride layer,
wherein the at least one cycle is performed at a temperature at or less than about 580° C.

10. The method of claim 9, wherein the metal nitride template layer comprises MN.

11. The method of claim 9, wherein the metal nitride template layer has a thickness of about 10-40 nm.

12. The method of claim 9, wherein the organometallic precursor comprises trimethyl aluminum (TMA), tris(demethylamido) aluminum (TDMAA) or tris(diethylamido) aluminum (TDEAA).

13. The method of claim 9, wherein the nitrogen-containing co-reactant comprises hydrazine (N₂H₄) or ammonia (NH₃).

14. The method of claim 9, wherein the metal nitride template layer has an average crystallite size of about 10 nm or greater.

15. The method of claim 9, wherein the second metal nitride layer comprises MN, GaN, or InGaN.

16. The method of claim 9, wherein the second metal nitride layer comprises MN.

17. The method of claim 9, wherein deposition of the second metal nitride layer comprises sputtering.

18. The method of claim 9, wherein the second metal nitride layer is deposited at a temperature of about 100° C. or less.

19. The method of claim 9, wherein the second metal nitride layer is deposited without active substrate heating.

20. The method of claim 9, wherein the second metal nitride layer has a thickness of about 150-170 nm.

21. A method of preparing a crystalline metal nitride layer comprising at least one cycle of:
exposing a surface of a Si or SiC substrate to an TDMAA or TDEAA chemical precursor; and
exposing the TDMAA or TDEAA chemical precursor to a N₂H₄ co-reactant to provide an AlN template layer on the substrate, followed by,
depositing a an AlN, GaN, or InGaN layer on the template layer to provide the crystalline metal nitride layer,
wherein the at least one cycle comprises pulsed CVD, wherein the at least one cycle is performed at a temperature at or less than about 580° C., and wherein deposition of the AlN, GaN, or InGaN layer comprises sputtering.
